(19) United States
(12) Patent Application Publication
(10) Pub. No.: US 2015/0048723 A1
(43) Pub. Date: Feb. 19, 2015

(54) PIEZOELECTRIC VIBRATION ELEMENT AND VIBRATION ELEMENT PACKAGE HAVING THE SAME

(71) Applicant: SAMSUNG ELECTRO-MECHANICS CO., LTD., Suwon-Si (KR)

(72) Inventors: Jong-Pil LEE, Suwon-Si (KR); Sang-Yeob CHA, Suwon-Si (KR)

(21) Appl. No.: 14/457,998

(22) Filed: Aug. 12, 2014

(30) Foreign Application Priority Data
Aug. 13, 2013 (KR) 10-2013-0095984

(51) Int. Cl. H01L 41/047; H01L 41/09

(52) U.S. Cl. CPC H01L 41/0475; H01L 41/09
USPC 310/365

(57) ABSTRACT

A piezoelectric vibration element and a vibration element package having the same are disclosed. The piezoelectric vibration element and the vibration element package having the same in accordance with the present invention includes: a vibrating piece having a first mesa portion and a second mesa portion, which are vibrated by electric signals, formed on one surface and the other surface thereof, respectively; a first excitation electrode formed on the first mesa portion and configured to transfer the electric signals to the first mesa portion; a second excitation electrode formed on the second mesa portion and configured to transfer the electric signals to the second mesa portion; a first post formed on the one surface of the vibrating piece in such a way that one end thereof connected with a lateral surface of the first mesa portion has a same height as that of the first mesa portion; a first connection electrode formed on the first post so that the electric signals supplied from outside are received and transferred to the first excitation electrode; and a second connection electrode formed on the vibrating piece so that the electric signals supplied from outside are received and transferred to the second excitation electrode.

### CROSS-REFERENCE TO RELATED APPLICATIONS

This application claims the benefit of Korean Patent Application No. 10-2013-0095984, filed with the Korean Intellectual Property Office on Aug. 13, 2013, the disclosure of which is incorporated herein by reference in its entirety.

### BACKGROUND

1. Technical Field

The present invention relates to a piezoelectric vibration element and a vibration element package having the same.

2. Background Art

A crystal oscillator is an apparatus that uses resonance of a crystal piece caused by a piezoelectric phenomenon to create a certain frequency, when voltage is supplied from outside.

Crystal oscillators are used in various applications, such as frequency oscillators and frequency converters. Used as the piezoelectric material for crystal oscillators are crystals, which have good piezoelectric characteristics and thus function as a stable mechanical resonance generator.

Owing to stable frequencies they generate, crystal oscillators are used for computers and oscillator circuits of communication devices, and are often used as key components for reference for all signals.

The related art of the present invention is disclosed in Korea Patent Publication No. 10-2012-0117124 (QUARTZ VIBRATOR AND ELECTRODE STRUCTURE THEREOF; laid open on Oct. 24, 2012).

### SUMMARY

The present invention provides a piezoelectric vibration element and a vibration element package having the same in which an electrode is supported by a post.

An aspect of the present invention provides a piezoelectric vibration element, which includes: a vibrating piece having a first mesa portion and a second mesa portion, which are vibrated by electric signals, formed on one surface and the other surface thereof, respectively; a first excitation electrode formed on the first mesa portion and configured to transfer the electric signals to the first mesa portion; a second excitation electrode formed on the second mesa portion and configured to transfer the electric signals to the second mesa portion; a first post formed on the one surface of the vibrating piece in such a way that one end thereof connected with a lateral surface of the first mesa portion has a same height as that of the first mesa portion; a first connection electrode formed on the first post so that the electric signals supplied from outside are received and transferred to the first excitation electrode; and a second connection electrode formed on the vibrating piece so that the electric signals supplied from outside are received and transferred to the second excitation electrode.

The first mesa portion can be formed to be slated on the one surface of the vibrating piece, and the first post can be connected with one lateral surface of the first mesa portion that forms an acute angle with the one surface of the vibrating piece.

An upper surface of the first post can be positioned on a same plane as an upper surface of the first mesa portion.

The piezoelectric vibration element can further include a first lead electrode interposed between the first excitation electrode and the first connection electrode and configured to electrically connect the first connection electrode with the first excitation electrode.

The first post can be extended to a lower portion of the first lead electrode to support the first lead electrode.

The second connection electrode can be formed on the one surface of the vibrating piece.

The piezoelectric vibration element can further include a second post being formed between the second connection electrode and the one surface of the vibrating piece so as to support the second connection electrode formed on the one surface of the vibrating piece.

An upper surface of the second post can be positioned on a same plane as an upper surface of the first mesa portion and an upper surface of the first post.

The piezoelectric vibration element can further include a third post formed on the other surface of the vibrating piece in such a way that one end thereof being connected with a lateral surface of the second mesa portion has a same height as that of the second mesa portion, and the second connection electrode can be formed on the third post.

An upper surface of the third post can be positioned on a same plane as an upper surface of the second mesa portion.

The piezoelectric vibration element can further include a second lead electrode interposed between the second excitation electrode and the second connection electrode and configured to electrically connect the second connection electrode with the second excitation electrode, and the third post can be extended to a lower portion of the second lead electrode to support the second lead electrode.

The first connection electrode can be extended to the other surface of the vibrating piece.

The piezoelectric vibration element can further include a fourth post formed between the first connection electrode and the other surface of the vibrating piece so as to support the first connection electrode extended to the other surface of the vibrating piece.

An upper surface of the fourth post can be positioned on a same plane as an upper surface of the third post and an upper surface of the second mesa portion.

Another aspect of the present invention provides a vibration element package, which includes: a housing having a receiving space provided therein; an electrode pad formed in the housing; and a piezoelectric vibration element being received in the receiving space and coupled to one side of the electrode pad to be vibrated by electric signals. The piezoelectric vibration element can include: a vibrating piece having a first mesa portion and a second mesa portion formed on one surface and the other surface thereof, respectively, the first mesa portion and the second mesa portion being vibrated by the electric signals; a first excitation electrode formed on the first mesa portion and configured to transfer the electric signals to the first mesa portion; a second excitation electrode formed on the second mesa portion and configured to transfer the electric signals to the second mesa portion; a first post formed on the one surface of the vibrating piece in such a way that one end thereof connected with a lateral surface of the first mesa portion has a same height as that of the first mesa portion; a first connection electrode formed on the first post so as to be electrically connected with the electrode pad in order to receive the electric signals through the electrode pad and transfer the electric signals to the first excitation electrode; and a second connection electrode formed on the vibrating piece in order to receive the electric signals through the electrode pad and transfer the electric signals to the second excitation electrode.

The first mesa portion can be formed to be slated on the one surface of the vibrating piece, and the first post can be connected with one lateral surface of the first mesa portion that forms an acute angle with the one surface of the vibrating piece.

An upper surface of the first post can be positioned on a same plane as an upper surface of the first mesa portion.

The vibration element package can further include a first lead electrode interposed between the first excitation electrode and the first connection electrode and configured to electrically connect the first connection electrode with the first excitation electrode, and the first post can be extended to a lower portion of the first lead electrode to support the first lead electrode.

The second connection electrode can be formed on the one surface of the vibrating piece, and a second post can be formed between the second connection electrode and the one surface of the vibrating piece so as to support the second connection electrode formed on the one surface of the vibrating piece.

The vibration element package can further include a third post formed on the other surface of the vibrating piece in such a way that one end thereof being connected with a lateral surface of the second mesa portion has a same height as that of the second mesa portion, and the second connection electrode can be formed on the third post.

The vibration element package can further include a second lead electrode interposed between the second excitation electrode and the second connection electrode and configured to electrically connect the second connection electrode with the second excitation electrode, and the third post can be extended to a lower portion of the second lead electrode to support the second lead electrode.

The first connection electrode can be extended to the other surface of the vibrating piece, and a fourth post can be formed between the first connection electrode and the other surface of the vibrating piece so as to support the first connection electrode extended to the other surface of the vibrating piece.

According to an embodiment of the present invention, it becomes possible to prevent short-circuit of a piezoelectric vibration element, and thus an electric field efficiency can be improved.

According to another embodiment of the present invention, a defective rate caused by short-circuit of electrodes of a vibration element package can be reduced.

### BRIEF DESCRIPTION OF THE DRAWINGS

FIG. 1 shows a vibration element package in accordance with an embodiment of the present invention.

FIG. 2 shows a piezoelectric vibration element in accordance with an embodiment of the present invention.

FIG. 3 shows both surfaces of the piezoelectric vibration element in accordance with an embodiment of the present invention.

FIG. 4 is a cross-sectional view showing the piezoelectric vibration element in accordance with an embodiment of the present invention.

### DETAILED DESCRIPTION

Hereinafter, certain embodiments of a piezoelectric vibration element and a vibration element package having the same in accordance with the present invention will be described in detail with reference to the accompanying drawings. In describing certain embodiments of the present invention with reference to the accompanying drawings, any identical or corresponding elements will be assigned with same reference numerals, and their redundant description will not be provided.

Terms such as “first” and “second” can be used in describing various elements, but the above elements shall not be restricted to the above terms. The above terms are used only to distinguish one element from the other.

When one element is described as being “coupled” or “connected” to another element, it shall be construed as not only being in physical contact with the other element but also as possibly having a third element interposed therebetween and each of the one element and the other element being in contact with the third element.

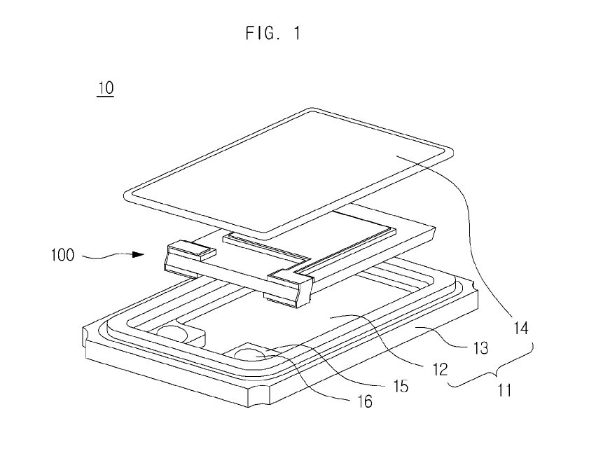

FIG. 1 shows a vibration element package in accordance with an embodiment of the present invention.

A vibration element package 10 in accordance with an embodiment of the present invention can include housing 11, electrode pad 15 and piezoelectric vibration element 100.

The housing 11 can include bottom portion 12, support portion 13 and lid 14. The bottom portion 12 can be made of metal, ceramic or polymer. The support portion 13 is formed to surround the bottom portion 12 and to provide a space for receiving the piezoelectric vibration element 100. The support portion 13 can be integrally formed with the bottom portion 12 and can be made of metal, ceramic or polymer. The lid 14 is disposed above the support portion 13 and is configured to seal the receiving space formed by the bottom portion 12 and the support portion 13.

The electrode pad 15 is formed in the housing 11 and is a part to which the piezoelectric vibration element 100 is coupled. The electrode pad 15 can be formed in a pair on the bottom portion 12 of the housing 11. One end of the piezoelectric vibration element 100 is coupled to the electrode pad 15 and is vibrated by electric signals. Moreover, conductive adhesive 16 can be interposed between the electrode pad 15 and the piezoelectric vibration element 100.

Hereinafter, the piezoelectric vibration element 100, which is received in the housing 11, will be described.

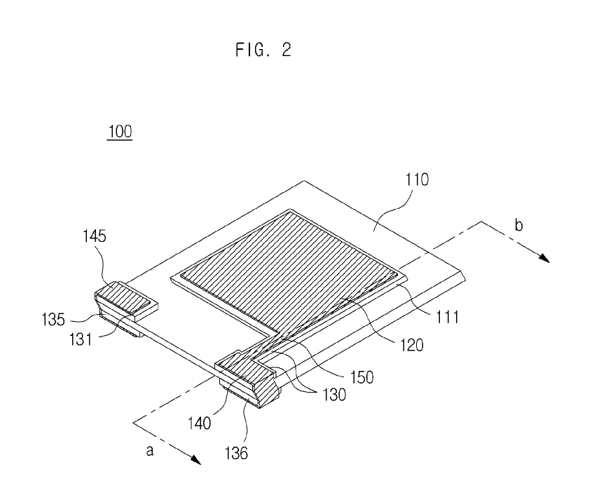

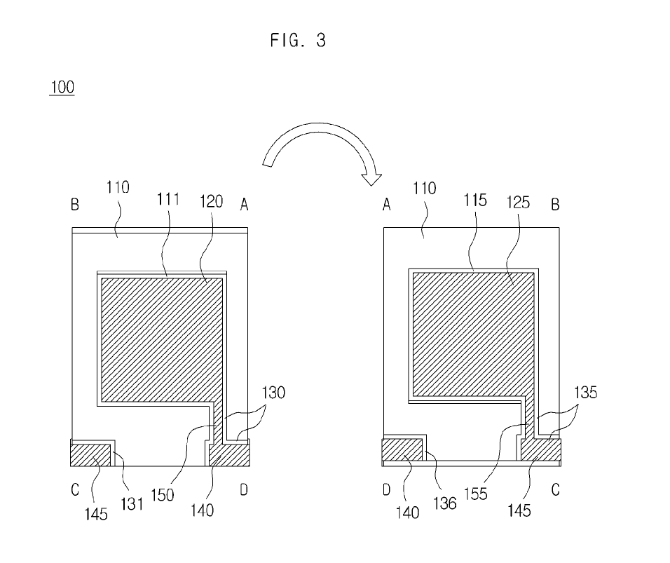

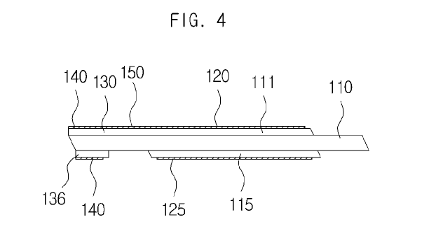

FIG. 2 shows a piezoelectric vibration element in accordance with an embodiment of the present invention. FIG. 3 shows both surfaces of the piezoelectric vibration element in accordance with an embodiment of the present invention. FIG. 4 is a cross-sectional view showing the piezoelectric vibration element in accordance with an embodiment of the present invention.

Referring to FIG. 2 to FIG. 4, the piezoelectric vibration element 100 in accordance with an embodiment of the present invention can include a vibrating piece 110, a first excitation electrode 120, a second excitation electrode 125, a first post 130, a second post 131, a third post 135, a fourth post 136, a first connection electrode 140, a second connection electrode 145, a first lead electrode 150 and a second lead electrode 155.

The vibrating piece 110 is a piezoelectric material that is vibrated by electric signals. The vibrating piece 110 can be made of a crystal.

The vibrating piece 110 can have a first mesa portion 111 and a second mesa portion 115 formed thereon. The first mesa portion 111 and the second mesa portion 115 are protruded outwardly on one surface and the other surface of the vibrating piece 110, respectively, and both have top surfaces that are flat. By having the first mesa portion 111 and the second mesa portion 115 formed on the vibrating piece 110, a stepped difference is formed in the vibrating piece 110. The first mesa portion 111 and the second mesa portion 115 can be formed when the vibrating piece 110 is etched.

When viewed from a lateral side, the first mesa portion 111 and the second mesa portion 115 are formed askew. For instance, the first mesa portion 111, which has a rectangular shape, is slanted toward one side so that one lateral surface of the first mesa portion 111 forms an acute angle with a surface of the vibrating piece 110, and the other lateral surface of the first mesa portion 111 forms an obtuse angle with the surface of the vibrating piece 110.

The first mesa portion 111 and the second mesa portion 115 are vibrated intensively at the vibrating piece 110 by electric signals. In such a case, the first mesa portion 111 and the second mesa portion 115 vibrate in horizontal but opposite directions to each other, thereby allowing the vibrating piece 110 to have slip vibrations.

The first excitation electrode 120 is formed on the first mesa portion 111 and can transfer electric signals to the first mesa portion 111 in order to vibrate the first mesa portion 111.

The second excitation electrode 125, which forms a pair with the first excitation electrode 120, is formed on the second mesa portion 115 and can transfer electric signals to the second mesa portion 115 in order to vibrate the second mesa portion 115.

The first post 130 is a support connected with a lateral surface of the first mesa portion 111. The first post 130 is formed on one surface of the vibrating piece 110, and one of the first post 130 that is connected with the first mesa portion 111 can have a same height as the first mesa portion 111. Since there is no stepped difference between the first excitation electrode 120 and the first connection electrode 140, owing to the first post 130, it becomes possible to prevent short-circuit between the first excitation electrode 120 and the first connection electrode 140.

Specifically, the first post 130 can be connected with the one lateral surface of the first mesa portion 111 that forms an acute angle with the one surface of the vibrating piece 110. Without the first post 130, electrodes can be readily short-circuited because an electrode has to be formed on the one lateral surface of the first mesa portion 111 that forms an acute angle with the one surface of the vibrating piece 110. However, there is no stepped difference between the first excitation electrode 120 and the first connection electrode 140, owing to the first post 130, short-circuit can be readily prevented.

An upper surface of the first post 130 can be formed to be flat. Here, the upper surface of the first post 130 can be positioned on a same plane as an upper surface of the first mesa portion 111. By positioning the upper surface of the first post 130 on the same plane as the upper surface of the first mesa portion 111, the electrodes can be formed to be flat, making it easier to form the electrodes.

The first connection electrode 140 receives electric signals supplied from outside and transfers the electric signals to the first excitation electrode 120. The first connection electrode 140 is the portion that is connected with the electrode pad 15 of the vibration element package 10 and can be electrically connected with the first excitation electrode 120.

The first connection electrode 140 can be formed on the first post 130. In the case where the first connection electrode 140 is formed on the first post 130, no stepped difference occurs at a boundary between the first excitation electrode 120 and the first connection electrode 140, making it possible to prevent short-circuit of the electrodes.

The first connection electrode 140 can be formed at an end portion of one surface of the vibrating piece 110. Moreover, the first connection electrode 140 can be extended to the other surface of the vibrating piece 110. In such a case, the first connection electrode 140 can be formed to be symmetrical about the vibrating piece 110. As such, in the case where the first connection electrode 140 is formed on the one surface and the other surface of the vibrating piece 110, either surface of the vibrating piece 110 can be freely used.

The second connection electrode 145, which forms a pair with the first connection electrode 140, receives electrical signals supplied from outside and transfer the electrical signals to the second excitation electrode 125. The second connection electrode 145 is the portion that is connected with the electrode pad 15 of the vibration element package 10 and can be electrically connected with the second excitation electrode 125.

The second connection electrode 145 can be formed at an end portion of the vibrating piece 110, and in case the vibrating piece 110 is in a rectangular shape, the second connection electrode 145 is formed on a same side as the first connection electrode 140. Through this, one side of the vibrating piece 110 can be coupled to the electrode pad 15.

Moreover, the second connection electrode 145 can be formed on one surface of the vibrating piece 110. That is, the first connection electrode 140 and the second connection electrode 145 can be formed on a same surface of the vibrating piece 110. In such a case, even if the electrode pad 15 is formed on one surface of the housing 11 only, the vibrating piece 110 can be sufficiently vibrated.

Not only can the second connection electrode 145 be formed on one surface of the vibrating piece 110, but the second connection electrode 145 can be extended to the other surface of the vibrating piece 110, in which case the second connection electrode 145 can be formed to be symmetrical about the vibrating piece 110.

The first connection electrode 140 and the second connection electrode 145 can be each formed on both one surface and the other surface of the vibrating piece 110, and in case their positions and shapes are symmetrical, either surface of the vibrating piece 110 can be freely coupled to the electrode pad 15.

The second post 131 is a support that supports the second connection electrode 145 formed on the one surface of the vibrating piece 110 and can be formed between the second connection electrode 145 and the one surface of the vibrating piece 110. In such a case, an upper surface of the second post 131 can be positioned on a same plane as the upper surface of the first mesa portion 111 and the upper surface of the first post 130.

With the second post 131, the second connection electrode 145 and the first connection electrode 140 can be formed at a same height and thus can be readily coupled with the electrode pad 15, and as the vibrating piece 110 can be sufficiently thick, thereby preventing a crack.

The first lead electrode 150 is interposed between the first excitation electrode 120 and the first connection electrode 140 to electrically connect the first connection electrode 140 with the first excitation electrode 120. With the first lead electrode 150, the first excitation electrode 120 and the first connection electrode 140 can be electrically connected with each other even if the first excitation electrode 120 and the first connection electrode 140 are separated apart.

Here, the first post 130 can be extended to a lower portion of the first lead electrode 150 to support the first lead electrode 150. Accordingly, since the first lead electrode 150 is also formed on the first post 130, short-circuit of the first lead electrode 150 can be also prevented.

The second lead electrode 155 is interposed between the second excitation electrode 125 and the second connection electrode 145 to electrically connect the second connection electrode 145 with the second excitation electrode 125. With the second lead electrode 155, the second excitation electrode 125 and the second connection electrode 145 can be electrically connected with each other even if the second excitation electrode 125 and the second connection electrode 145 are separated apart.

The third post 135, which is connected to a lateral surface of the second mesa portion 115, is a support that is formed on the other surface of the vibrating piece 110 in such a way that one end thereof, which is connected with the lateral surface of the second mesa portion 115, has a same height as the second mesa portion 115. The third post 135 can support the second connection electrode 145. That is, the second connection electrode 145 can be formed on the third post 135. With the third post 135, short-circuit can be prevented between the second excitation electrode 125 and the second connection electrode 145, similarly to the effect of the first post 130.

The third post 135 can be extended to a lower portion of the second lead electrode 155 to support the second lead electrode 155. In other words, the second lead electrode 155 can be formed on the third post 135. This is to prevent the second lead electrode 155 from short-circuit.

An upper surface of the third post 135 can be formed on a same plane as an upper surface of the second mesa portion 115. In such a case, since the second connection electrode 145 and the second excitation electrode 125 are formed on a same plane, short-circuit of electrodes can be maximally prevented.

In the case where the first connection electrode 140 is extended to the other surface of the vibrating piece 110, the fourth post 136 is a support that is formed between the first connection electrode 140 and the vibrating piece 110 so as to support the first connection electrode 140 extended to the other surface of the vibrating piece 110.

An upper surface of the fourth post 136 can be positioned on a same plane as the upper surface of the second mesa portion 115. Accordingly, the electrodes can be formed on the same plane.

The shapes of the first mesa portion 111, the first excitation electrode 120, the first post 130, the second post 131, the first connection electrode 140 and the first lead electrode 150 can be symmetrical with those of the second mesa portion 115, the second excitation electrode 125, the third post 135, the fourth post 136, the second connection electrode 145 and the second lead electrode 155, respectively, about the vibrating piece 110. Accordingly, either surface of the piezoelectric vibration element 100 can be utilized.

As described above, by forming an electrode pattern by use of posts according to the piezoelectric vibration element and the vibration element package having the same in accordance an embodiment of the present invention, it is possible to prevent short-circuit of electrodes, thereby reducing an open fail of the electrodes.

Although certain embodiments of the present invention have been described, it shall be appreciated that a number of permutations and modifications of the present invention are possible by those who are ordinarily skilled in the art to which the present invention pertains by supplementing, modifying, deleting and/or adding some elements without departing from the technical ideas of the present invention that are disclosed in the claims appended below and that such permutations and modifications are also covered by the scope of the present invention.

What is claimed is:

1. A piezoelectric vibration element comprising:
a vibrating piece having a first mesa portion and a second mesa portion formed on one surface and the other surface thereof, respectively, the first mesa portion and the second mesa portion being vibrated by electric signals;
a first excitation electrode formed on the first mesa portion and configured to transfer the electric signals to the first mesa portion;
a second excitation electrode formed on the second mesa portion and configured to transfer the electric signals to the second mesa portion;
a first post formed on the one surface of the vibrating piece in such a way that one end thereof connected with a lateral surface of the first mesa portion has a same height as that of the first mesa portion;
a first connection electrode formed on the first post so that the electric signals supplied from outside are received and transferred to the first excitation electrode; and
a second connection electrode formed on the vibrating piece so that the electric signals supplied from outside are received and transferred to the second excitation electrode.

2. The piezoelectric vibration element of claim 1, wherein the first mesa portion is formed to be slated on the one surface of the vibrating piece, and
wherein the first post is connected with one lateral surface of the first mesa portion that forms an acute angle with the one surface of the vibrating piece.

3. The piezoelectric vibration element of claim 1, wherein an upper surface of the first post is positioned on a same plane as an upper surface of the first mesa portion.

4. The piezoelectric vibration element of claim 1, further comprising a first lead electrode interposed between the first excitation electrode and the first connection electrode and configured to electrically connect the first connection electrode with the first excitation electrode.

5. The piezoelectric vibration element of claim 4, wherein the first post is extended to a lower portion of the first lead electrode to support the first lead electrode.

6. The piezoelectric vibration element of claim 1, wherein the second connection electrode is formed on the one surface of the vibrating piece.

7. The piezoelectric vibration element of claim 6, further comprising a second post being formed between the second connection electrode and the one surface of the vibrating piece so as to support the second connection electrode formed on the one surface of the vibrating piece.

8. The piezoelectric vibration element of claim 7, wherein an upper surface of the second post is positioned on a same plane as an upper surface of the first mesa portion and an upper surface of the first post.

9. The piezoelectric vibration element of claim 1, further comprising a third post formed on the other surface of the vibrating piece in such a way that one end thereof being connected with a lateral surface of the second mesa portion has a same height as that of the second mesa portion,
wherein the second connection electrode is formed on the third post.

10. The piezoelectric vibration element of claim 9, wherein an upper surface of the third post is positioned on a same plane as an upper surface of the second mesa portion.

11. The piezoelectric vibration element of claim 9, further comprising a second lead electrode interposed between the second excitation electrode and the second connection electrode and configured to electrically connect the second connection electrode with the second excitation electrode,
wherein the third post is extended to a lower portion of the second lead electrode to support the second lead electrode.

12. The piezoelectric vibration element of claim 9, wherein the first connection electrode is extended to the other surface of the vibrating piece.

13. The piezoelectric vibration element of claim 12, further comprising a fourth post formed between the first connection electrode and the other surface of the vibrating piece so as to support the first connection electrode extended to the other surface of the vibrating piece.

14. The piezoelectric vibration element of claim 13, wherein an upper surface of the fourth post is positioned on a same plane as an upper surface of the third post and an upper surface of the second mesa portion.

15. A vibration element package comprising:
a housing having a receiving space provided therein;
an electrode pad formed in the housing; and
a piezoelectric vibration element being received in the receiving space and coupled to one side of the electrode pad to be vibrated by electric signals,
wherein the piezoelectric vibration element comprises:
a vibrating piece having a first mesa portion and a second mesa portion formed on one surface and the other surface thereof, respectively, the first mesa portion and the second mesa portion being vibrated by the electric signals;
a first excitation electrode formed on the first mesa portion and configured to transfer the electric signals to the first mesa portion;
a second excitation electrode formed on the second mesa portion and configured to transfer the electric signals to the second mesa portion;
a first post formed on the one surface of the vibrating piece in such a way that one end thereof connected with a lateral surface of the first mesa portion has a same height as that of the first mesa portion;
a first connection electrode formed on the first post so as to be electrically connected with the electrode pad in order to receive the electric signals through the electrode pad and transfer the electric signals to the first excitation electrode; and
a second connection electrode formed on the vibrating piece in order to receive the electric signals through the electrode pad and transfer the electric signals to the second excitation electrode.

16. The vibration element package of claim 15, wherein the first mesa portion is formed to be slated on the one surface of the vibrating piece, and
wherein the first post is connected with one lateral surface of the first mesa portion that forms an acute angle with the one surface of the vibrating piece.

17. The vibration element package of claim 15, wherein an upper surface of the first post is positioned on a same plane as an upper surface of the first mesa portion.

18. The vibration element package of claim 15, further comprising a first lead electrode interposed between the first excitation electrode and the first connection electrode and configured to electrically connect the first connection electrode with the first excitation electrode,
wherein the first post is extended to a lower portion of the first lead electrode to support the first lead electrode.

19. The vibration element package of claim 15, wherein the second connection electrode is formed on the one surface of the vibrating piece, and
wherein a second post is formed between the second connection electrode and the one surface of the vibrating piece so as to support the second connection electrode formed on the one surface of the vibrating piece.

20. The vibration element package of claim 15, further comprising a third post formed on the other surface of the vibrating piece in such a way that one end thereof being connected with a lateral surface of the second mesa portion has a same height as that of the second mesa portion,
wherein the second connection electrode is formed on the third post.

21. The vibration element package of claim 20, further comprising a second lead electrode interposed between the second excitation electrode and the second connection electrode and configured to electrically connect the second connection electrode with the second excitation electrode,
wherein the third post is extended to a lower portion of the second lead electrode to support the second lead electrode.

22. The vibration element package of claim 20, wherein the first connection electrode is extended to the other surface of the vibrating piece, and
wherein a fourth post is formed between the first connection electrode and the other surface of the vibrating piece so as to support the first connection electrode extended to the other surface of the vibrating piece.
